(19) United States
(12) Patent Application Publication
(10) Pub. No.: US 2007/0016842 A1
(43) Pub. Date: Jan. 18, 2007

(54) Method and apparatus for configuring a cyclic redundancy check (CRC) generation circuit to perform CRC on a data stream

(75) Inventors: Roshan J. Samuel, Queen Creek, AZ (US); Rawin Rojvanit, Chandler, AZ (US)

Correspondence Address: BAKER BOTTS L.L.P.;PATENT DEPARTMENT, 98 SAN JACINTO BLVD., SUITE 1500, AUSTIN, TX, 78701-4039, US

(73) Assignee: Microchip Technology Incorporated

(21) Appl. No.: 11/180,821

(22) Filed: Jul. 13, 2005

(51) Int. Cl. H03M 13/00

(52) U.S. Cl. 714/781

(57) ABSTRACT

A method and apparatus for configuring a cyclic redundancy check (CRC) generation circuit to perform CRC on a data stream are disclosed. The method includes storing a generator polynomial associated with a CRC equation in a register, where the generator polynomial has a length capable of varying such that the length has any value less than or equal to a number of bits associated with a CRC generation circuit. A bit position of the CRC generation circuit that corresponds to the length of the generator polynomial is selected by using a first multiplexer to generate a feedback value. The CRC generation circuit is programmed to calculate a CRC checksum based on the generator polynomial stored in the register and the feedback value from the selected bit position.

### TECHNICAL FIELD

The present disclosure relates generally to error checking in a microcontroller, and more particularly to a method and apparatus for configuring a cyclic redundancy check (CRC) generation circuit to perform error checking on a data stream.

### BACKGROUND

Today, it is common to use error checking techniques for data being transmitted between systems or between functional units of a chip. One type of error detecting technique frequently used for digital data is the cyclic redundancy check (CRC). In a CRC calculation, the data is treated by the CRC equation as a binary number. The data, in the form of a binary number, is then divided by another binary number known as the CRC polynomial. The remainder of the calculation is the CRC checksum, which may be appended to the end of the data for error checking purposes. The data may be checked for errors when it is received at its destination by dividing the data and the appended CRC checksum by the same CRC polynomial used to calculate the CRC checksum. If the result of the division is zero, then the data transmission was successful. If the result of the division is not zero, an error to the data occurred during transmission.

The CRC checksum may be generated by hardware or software. Conventional hardware CRC generators are typically hardwired to one polynomial that has a fixed length. These hardware CRC generators, therefore, may only calculate a CRC checksum using one CRC equation. A single CRC equation may be suitable for an application specific device. In general purpose devices, however, a single CRC equation may not provide the required error detecting capabilities for all types of data. In these devices, the use of more than one CRC equation may require multiple instantiations of the CRC generator, where each CRC generator is hardwired to a different CRC polynomial. This solution may be undesirable because extra transistors must be added for each of the instantiations, thus increasing the size of the circuitry and the cost of the chip.

The CRC checksum may also be calculated via software executing on a processor. Using a software program to calculate the CRC checksum may provide the flexibility needed for a general purpose device since any CRC equation may be used. The drawback to software, however, is computational speed because the software running on a processor cannot achieve the same throughput as dedicated hardware. Additionally, calculating the CRC checksum in software may use MIPs (million instructions per second) that could be used for other purposes.

### SUMMARY

The present disclosure overcomes the above-identified problems as well as other shortcomings and deficiencies of existing technologies by providing an apparatus, system and method for generating a configurable cyclic redundancy check (CRC) code.

In a specific example embodiment, according to the present disclosure, a method for configuring a CRC generation circuit to perform CRC on a data stream includes storing a generator polynomial associated with a CRC equation in a register, where the generator polynomial has a length capable of varying such that the length has any value less than or equal to a number of bits associated with a CRC generation circuit. A bit position of the CRC generation circuit that corresponds to the length of the generator polynomial is selected by using a first multiplexer to generate a feedback value. The CRC generation circuit is programmed to calculate a CRC checksum based on the generator polynomial stored in the register and the feedback value from the selected bit position.

In another specific example embodiment, according to the present disclosure, circuitry for configuring a CRC generation circuit to perform CRC on a data stream includes a register that stores a generator polynomial associated with a CRC equation, where the generator polynomial has a length capable of varying such that the length has any value less than or equal to a maximum number of bits. A first multiplexer is coupled to the register and generates a feedback value based on the length of the generator polynomial. A CRC generation circuit is coupled to the register and the first multiplexer and calculates a CRC checksum based on the generator polynomial stored in the register and the feedback value, which is selected from a bit position of the CRC generation circuit that corresponds to the length of the generator polynomial.

In a further specific example embodiment, according to the present disclosure, a microcontroller includes a processor that generates a data stream and a register coupled to the processor that stores a generator polynomial associated with a CRC equation, where the generator polynomial has a length capable of varying such that the length has any value less than or equal to a maximum number of bits. A first multiplexer is coupled to the register and generates a feedback value based on the length of the generator polynomial. A CRC generation circuit is coupled to the register and the first multiplexer and calculates a CRC checksum for the data stream based on the generator polynomial stored in the register and the feedback value, which is selected from a bit position of the CRC generation circuit that corresponds to the length of the generator polynomial.

### BRIEF DESCRIPTION OF THE DRAWINGS

A more complete understanding of the present disclosure and advantages thereof may be acquired by referring to the following description taken in conjunction with the accompanying drawings wherein:

FIG. 1 is a block diagram of a system capable of transmitting data, in accordance with teachings of the present disclosure;

FIG. 2 is a schematic block diagram of a CRC generation circuit, in accordance with teachings of the present disclosure;

FIG. 3 is a logical representation of the CRC generation circuit for a specific example polynomial in accordance with teachings of the present disclosure; and

FIG. 4 is a flow diagram of a method for generating a configurable cyclic redundancy check (CRC) code.

While the present disclosure may be susceptible to various modifications and alternative forms. Specific example embodiments of the present disclosure are shown and are described herein in detail. It should be understood, however, that the description set forth herein of specific example embodiments is not intended to limit the present disclosure to the particular forms disclosed herein. Rather, all modifications and equivalents falling within the spirit and scope of the disclosure as defined by the appended claims are intended to be covered.

### DETAILED DESCRIPTION

Referring now to the drawings, the details of specific example embodiments are schematically illustrated. Like elements in the drawings will be represented by like numbers, and similar elements will be represented by like numbers with a different lower case letter suffix.

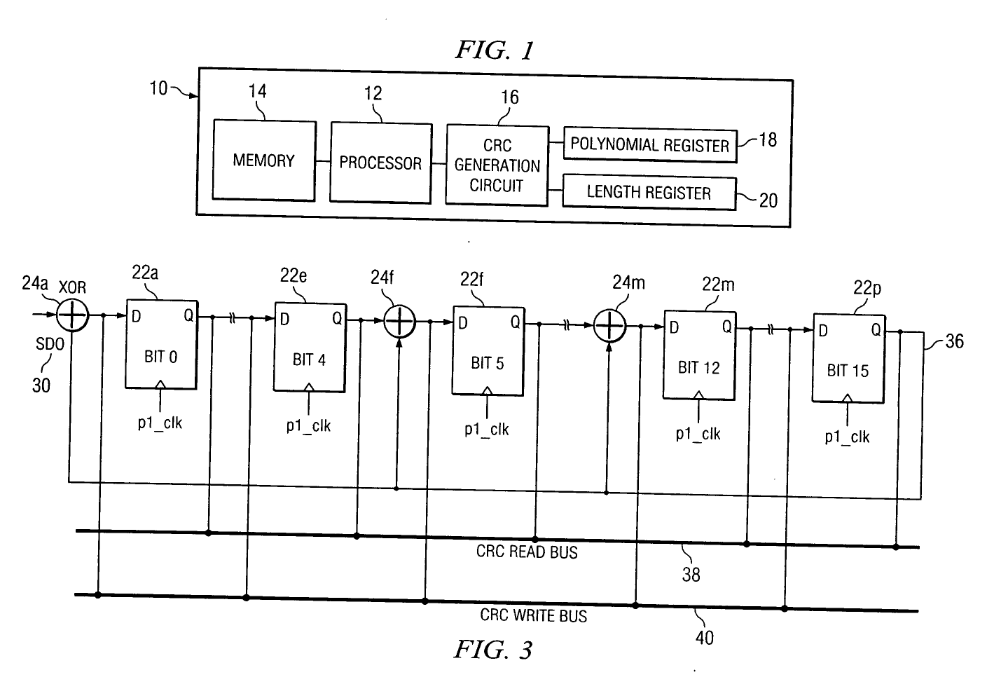

FIG. 1 illustrates a block diagram of system 10 that is capable of transmitting and receiving data. System 10 may include processor 12, memory 14, cyclic redundancy check (CRC) generation circuit 16, polynomial register 18 and length register 20. CRC generation circuit 16 may be programmable in order to generate different error checking values, also known as CRC checksums, that are appended at the end of a data stream. The CRC checksums may be calculated by dividing the data stream by a generator polynomial, where the CRC checksums are the remainder of the division. In the illustrated example embodiment, the generator polynomial may be stored in polynomial register 18 and the length of the generator polynomial may be stored in length register 20. The generator polynomial and its corresponding length may be programmed into CRC generation circuit 16 such that CRC generation circuit 16 calculates a CRC checksum for any data stream. CRC generation circuit 16, therefore, provides a way to use any CRC equation without increasing the cost or size of the chip (e.g., an integrated circuit) or decreasing the speed of the CRC checksum calculation.

Processor 12 may be a digital processor, microcontroller, microprocessor, digital signal processor (DSP), application specific integrated circuit (ASIC), programmable logic array (PLA) or any other digital or analog circuitry configured to execute processing instructions stored in memory 14. Memory 14 may be random access memory (RAM), electrically erasable programmable read-only memory (EEPROM), a PCMCIA card, flash memory, or any suitable selection and/or array of volatile or non-volatile memory. Polynomial register 18 and length register 20 may include a plurality of storage elements that are capable of storing binary information and are readable and writeable by processor 12.

Polynomial register 18 may be used to store a binary representation of a generator polynomial used by CRC generation circuit 16 to calculate a CRC checksum based on any CRC equation. Length register 20 may be used to store a binary representation of the length of the generator polynomial stored in polynomial register 18. The length may be determined based on the maximum polynomial term (e.g., the term having the highest exponential value) included in the generator polynomial. For example, a generator polynomial having the terms x¹⁶+x₁₂+x⁵+1 has a length of 16 bits because the x¹⁶ term is the polynomial term that has the highest exponential value.

CRC generation circuit 16 may be any type of circuit that is capable of calculating a CRC checksum using any type of CRC equation. In one embodiment, CRC generation circuit 16 may be implemented as a standard serial shifting CRC calculator. During operation of system 10, data may be transmitted between functional units in system 10 or to other systems. In order to assure that the data is transmitted without errors, CRC generation circuit 16 may be used to calculate a CRC checksum to be appended at the end of a data stream. The data may be stored in a data registers (not expressly shown). Processor 12 may determine the CRC equation needed to calculate a suitable CRC checksum for the stored data. A generator polynomial associated with the appropriate CRC equation may be stored in polynomial register 18 and the length of the generator polynomial may be stored in length register 20. The generator polynomial may be any suitable polynomial used to perform error checking on a data stream and may have a length equal to the length desired for the CRC checksum.

To calculate a CRC checksum, CRC generation circuit 16 may be programmed with the generator polynomial stored in polynomial register 18 and the length stored in length register 20 may be used to select the bit of CRC generation circuit 16 from which a feedback value is obtained. The data stream, as represented by a polynomial, may then be written into CRC generation circuit 16 such that CRC generation circuit 16 performs the following CRC equation to calculate the CRC checksum:
d(x)/g(x)=q(x)+s(x)/g(x)

where d(x) is a dividend polynomial d(x) that represents the data stream, q(x) is the quotient polynomial that is discarded after the division is performed, g(x) is the generator polynomial and s(x) is the remainder, which represents the CRC checksum for the data stream. Once the CRC checksum is calculated, the CRC checksum may be appended onto the end of the data stream such that an error check may be performed on the data stream. CRC generation circuit 16, in combination with registers 18 and 20, provides a low cost technique for calculating any CRC checksum in hardware without adding a large amount of circuitry to the chip or decreasing the speed of the calculation.

Although processor 12 is separate from other components of system 10 as illustrated in FIG. 1, memory 14, CRC generation circuit 16 and registers 18 and 20 may be integral to processor 12 such that each component is included on a single integrated circuit. Additionally, system 10 may include a timing reference (e.g., one or more clocks) and input/output (I/O) peripherals that are either separate from or integral with processor 12.

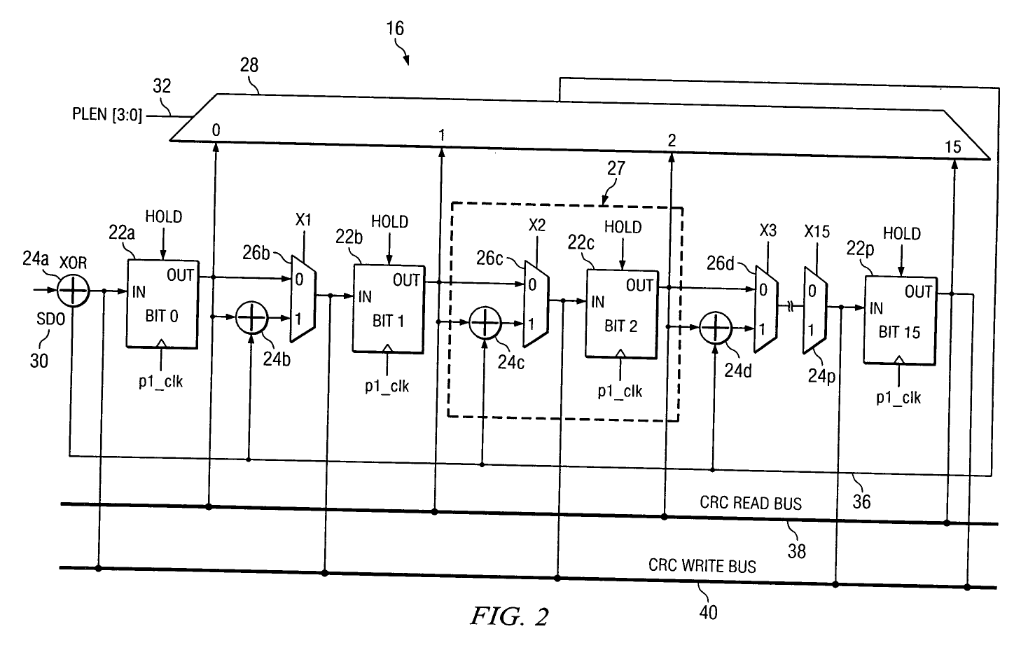

FIG. 2 illustrates a schematic block diagram of a programmable CRC generation circuit 16. CRC generation circuit 16 may include flip-flops 22a through 22p (generally referred to as flip-flops 22), feedback gates 24a through 24p (generally referred to as flip-flops 24), term multiplexers 26b through 26p (generally referred to as multiplexers 26) and feedback multiplexer 28. CRC generation circuit 16 may be programmed to calculate CRC checksums using multiple CRC equations that have different lengths. In order to calculate the CRC checksum associated with a particular data stream, the data stream, a generator polynomial may be programmed into CRC generation circuit 16 through the select inputs X[15:1] of term multiplexers 26 and the length of the generator polynomial may be programmed through the control input 32 of feedback multiplexer 28 such that a feedback value is selected from the output of flip-flop 22 at the bit position that corresponds to the length of the generator polynomial. CRC generation circuit 16, therefore, may be programmed with any generator polynomial used in a CRC equation and the length of the polynomial may be varied such that the length has any value that is less than or equal to the number of bits included in CRC generation circuit 16.

In the illustrated example embodiment, CRC generation circuit 16 includes sixteen bits and is implemented using a standard serial shifting CRC calculator that includes a plurality of flip-flops 22, a plurality of feedback gates 24 and a plurality of term multiplexers 26. Flip-flops 22 may be D flip-flops that trigger on either the positive or negative edge of p1_clk to write data into and read data from each of flip-flops 22. Feedback gates 24 may be XOR gates used to perform modulo-2 arithmetic to divide the polynomial representing the data stream by the generator polynomial. Term multiplexers 26 and feedback multiplexer 28 may be any combinational circuit that selects from at least two inputs and directs the selected input to a single output. In other embodiments, CRC generation circuit 16 may include fewer or more flip-flops 22, feedback gates 24 and/or term multiplexers 26 depending on the polynomial operations to be performed. For example, CRC generation circuit 16 may include thirty-two of flip flops 22, feedback gates 24 and/or term multiplexers 26 for CRC checksums that use 32 bit generator polynomials.

Each of flip-flops 22, feedback gates 24 and term multiplexers 26 may form polynomial block 27 such that a plurality of polynomial blocks 27 may be combined in series to form CRC generation circuit 16. As illustrated, the output of one polynomial block (e.g., the output of flip-flop 22b) is received by the input of an adjacent polynomial bock (e.g., one of the inputs of term multiplexer 26c). Bit 0 of CRC generation circuit 16 may not include term multiplexer 26 because the 0 bit required by most CRC equations is always XOR'd. Additionally, the illustrated example embodiment does not include polynomial block 27 for bit 16 because any 16 bit CRC equation assumes that the 16th bit is XOR'd. In other embodiments, polynomial block 27 may not be included for the maximum polynomial term of the CRC equation because it is assumed that the highest valid bit is XOR'd.

A CRC checksum may be calculated for any type of data by programming CRC generation circuit 16 with a generator polynomial to perform the appropriate CRC equation. The length of the generator polynomial may be obtained from length register 20 and may be used as control input 32 for feedback multiplexer 28 to select the appropriate bit of CRC generation circuit 16 to use as feedback value 36. Feedback value 36, therefore, may represent the maximum polynomial term in the generator polynomial. Once the length of the generator polynomial has been programmed, term multiplexers 26 may be used to configure CRC generation circuit 16 with the generator polynomial stored in polynomial register 18. As illustrated, each bit X[15:1] of polynomial register 18 may be used as the control input for each of term multiplexers 26. If the generator polynomial includes a specific polynomial term (e.g., xⁿ), a logical “1” may be stored in the corresponding bit position of polynomial register 18 and term multiplexer 26 may select the output of feedback gate 24. Otherwise, a logical “0” may be stored in the bit positions of polynomial register to indicate the generator polynomial does not include the specific polynomial term and term multiplexer 26 may select the output of adjacent polynomial block 27.

In one embodiment, CRC generation circuit 16 may receive the data for which the CRC checksum is to be calculated from dout 30, which is coupled to the most significant bit of the data register (not expressly shown). The data, as represented by a dividend polynomial stored in the data register, may be written into flip-flops 22 by shifting each bit, up to the highest valid bit as defined by the length stored in length register 20, on the rising edge of p1_clk into flip-flop 22a until each bit is stored in the appropriate one of flip-flops 22. Polynomial division may be performed as the data is shifted through flip-flops 22. The remainder, which represents the CRC checksum, may be the final contents of flip-flops 22 and the quotient may be shifted out of CRC generation circuit 16. In another embodiment, CRC generation circuit 16 may receive the data from CRC write bus 40. Processor 12 may be used to access the data register and directly write each bit of the data into the appropriate one of flip-flops 22 when the hold signal of each of flip-flops 22 is held low. Again, the length stored in length register 20 may be used to determine the highest bit of the data that should be written into flip-flops 22. Polynomial division may be performed once the data has been written into flip-flops 22 and the remainder that represents the CRC checksum may be stored in flip-flops 22. In either embodiment, the CRC checksum may be read from flip-flops 22 by processor 12 through CRC read bus 38.

FIG. 3 illustrates a logical representation of CRC generation circuit 16 programmed with an exemplary generator polynomial. As previously described, CRC generation circuit 16 may be programmed with any generator polynomial such that CRC generation circuit 16 may calculate the appropriate CRC checksum for a data stream by using the CRC equation associated with the generator poly. For example, Table 1 includes a list of generator polynomials used to generate a CRC checksum for different applications. The polynomials are meant to be illustrative but not inclusive of the generator polynomials that may be stored in polynomial register 18 and used by CRC generation circuit 16.

TABLE 1

| | | Binary | Polynomial |
|---|---|---|---|
| Common | | Representation | Length |
| Name | Polynomial | X[15:1] | PLEN[3:0] |
| CRC-12 | x¹² + x¹¹ + x³ + x² + | 000110000000111 | 1100 |
| | x + 1 | | |
| CRC-16 | x¹⁶ + x¹⁵ + x² + 1 | 100000000000010 | 1111 |
| CRC-16 | x¹⁶ + x¹⁴ + x + 1 | 010000000000001 | 1111 |
| Reverse | | | |
| CRC-CCITT | x¹⁶ + x¹² + x⁵ + 1 | 000100000010000 | 1111 |
| CRC-CCITT | x¹⁶ + x¹¹ + x⁴ + 1 | 000010000001000 | 1111 |
| Reverse | | | |

In the illustrated example embodiment, the generator polynomial for a CRC-CCITT calculation is programmed in CRC generation circuit 16. As shown in Table 1, the CRC-CCITT generator polynomial may be represented by the following equation:
x¹⁶+x¹²+x⁵+1

where each exponential term in the equation represents a polynomial term. The binary representation of the polynomial may be b000100000010000, where the logical “1” in the fifth and twelfth bit positions respectively represent the x⁵ and x¹² polynomial terms. The length of the generator polynomial may be determined based on a maximum polynomial term. For example, the highest polynomial term in the CRC-CCITT generator polynomial is x¹⁶. The binary representation of the length of the CRC-16 polynomial, therefore, is b1111.

In order to program the CRC-CCITT generator polynomial into CRC generation circuit 16, the bits X[15:1] in polynomial register 18 may be set as 000100000010000 and the bits PLEN[3:0] in length register 20 may be set as 1111. The length of the CRC-CCITT generator polynomial may be used as control input 32 of feedback multiplexer 28 (as shown in FIG. 2) to select the output of flip-flop 22p (e.g., the flip-flop associated with the 16th bit of CRC generation circuit 16) as feedback value 36. Once feedback value 36 has been determined, the binary representation of CRC-CCITT generator polynomial may be used as control inputs X[15:1] for term multiplexers 26 (as shown in FIG. 2). The logical “1” in the fifth and twelfth bit positions of the generator polynomial may be used by term multiplexers 26f and 26m to respectively select the outputs of feedback gates 24f and 24m. Once programmed with the CRC-CCITT generator polynomial, CRC generation circuit 16 performs the calculation by either shifting all bits of the data polynomial through CRC generation circuit 16 or writing the data polynomial in each of flip-flops 22 through CRC write bus 40. As illustrated, CRC generation circuit 16 calculates the CRC checksum by XORing feedback value 36 with the outputs of flip-flop 22e and 221. The results of the XOR of feedback value 36 and the output of flip-flop 22e may then be stored in flip-flip 22f and the results of the XOR of feedback value 36 and the output of flip-flop 221 may be stored in flip-flop 22m. Once the calculation is complete, the CRC checksum for the CRC equation may be read from flip-flops 22 through CRC read bus 38.

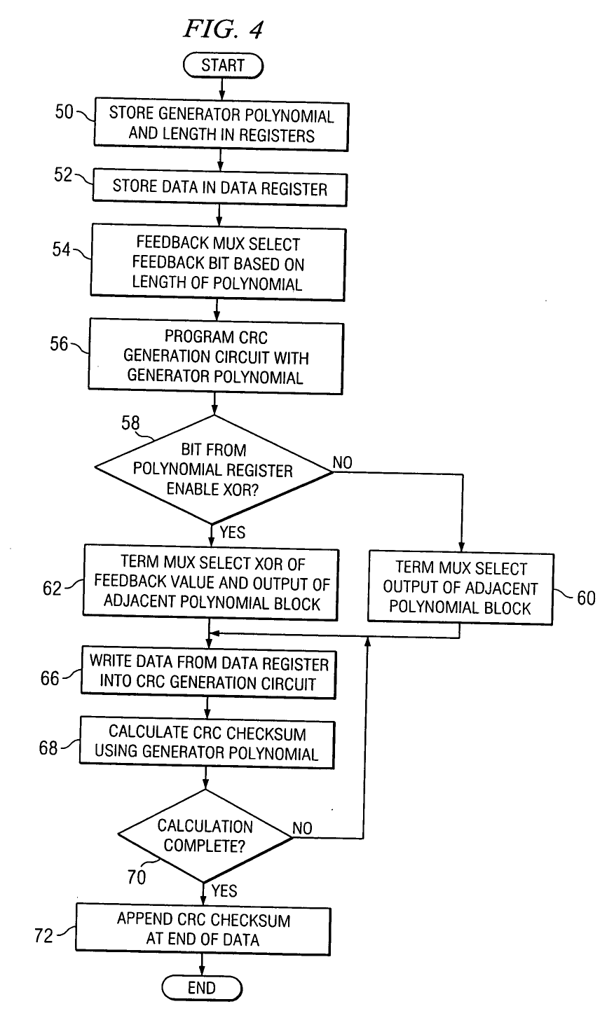

FIG. 4 illustrates a flow chart of a method for generating a configurable CRC code. Generally, a generator polynomial used in error checking for data operations may be translated into a binary value and stored in a register. The length of the polynomial may be determined based on a maximum polynomial term (e.g., the term having the highest exponential value) and stored in another register. During system operation, data may be generated by a system processor and written into a data register. In some instances, a CRC checksum may be calculated and appended at the end of the data such that error checking may be performed. The generator polynomial and its associated length may programmed in the CRC generation circuit in order to perform a CRC calculation on the data stored in the data register. Once the generator polynomial has been programmed, the data from the data register may be written into the CRC generation circuit and a CRC checksum for the data may be calculated with a CRC equation. By using a register to store a description of the generator polynomial and programming the CRC generation circuit with the generator polynomial, any suitable CRC checksum having any length may be calculated for each type of data generated by the system processor.

At step 50, a binary representation of a generator polynomial may be stored in polynomial register 18 and a binary representation of the length of the generator polynomial may be stored in length register 20. The binary representation may include a series of bits that describes the desired generator polynomial. For example, the CRC-CCITT polynomial x¹⁶+x¹²+x⁵+1 may translate to a binary value of 10001000000100001, where the polynomial terms in the equation are represented by a logical “1.” In one embodiment, the 16th and 0th bit may always be XOR'd such that the bits do not have to be stored in polynomial register 18. Therefore, as described in Table 1, the binary representation of the CRC-CCITT polynomial stored in polynomial register 18 may be X[15:1]=000100000010000. The length of the generator polynomial may be determined based on the maximum polynomial term (e.g., the polynomial term having the greatest exponential value). For example, the maximum term in the CRC-CCITT generator polynomial is x¹⁶ such that the length of the polynomial is 16 bits. The length, therefore, may translate to a binary value of 1111 and may be stored as PLEN [3:0] in length register 20. In one embodiment, processor 12 may be used to determine the appropriate generator polynomial to store in polynomial register 18 and may determine the length of the polynomial based on the maximum polynomial term by using programming instructions stored in memory 14 and/or software executed by processor 12.

A data polynomial, as represented by a binary number, may be stored in a data register by processor 12 at step 52. The data may be any type of data for which a CRC checksum may be calculated and appended on to the end of the data for error checking purposes. Although steps 50 and 52 have been described as being performed in a specific order, the steps may be performed in any order or contemporaneously.

At step 54, the length of the generator polynomial stored in length register 20 may be programmed into CRC generation circuit 16. The length may be used as control input 32 of feedback multiplexer 28 in order to determine the highest valid bit of the generator polynomial and select the output of flip-flops 22 at the highest valid bit in order to generate feedback value 36. The generator polynomial stored in polynomial register 18 may be programmed into CRC generation circuit at step 56. The generator polynomial may be used as control inputs X[15:1] of term multiplexers 26 to select either the output of feedback gates 24 or the output of adjacent polynomial block 27. Although steps 54 and 56 have been described as being performed in a specific order, the steps may be performed in any order or contemporaneously.

At step 58, term multiplexers 26 may determine if the generator polynomial stored in polynomial register 18 includes a polynomial term for the associated bit. In one embodiment, a logical “1” in the binary representation of the generator polynomial may signify that the generator polynomial includes a polynomial term for the corresponding bit position and a logical “0” may signify that the generator polynomial does not include the polynomial term for the corresponding bit position. If the control input of term multiplexer 26 is a logical “0”, term multiplexer 28 selects the output of adjacent polynomial block 27 at step 60. If the control input of term multiplexer 26 is a logical “1”, term multiplexer 26 selects the output of feedback gate 26 at step 62. In one embodiment, the output of feedback gate 26 may be an XOR of feedback value 36 and the output of adjacent polynomial block 27.

Once the generator polynomial has been programmed in CRC generation circuit 16, data from the data register may be written into CRC generation circuit at step 66. In one embodiment, the data may be shifted one bit at a time from the data register through dout 30 into CRC generation circuit 16 until each bit is stored in the corresponding one of flip-flops 22. In other embodiment, all bits of the data may be simultaneously written into the corresponding one of flip-flops 22 through CRC write bus 40. At step 68, CRC generation circuit 16 may be used to calculate the CRC checksum of the data based on the programmed generator polynomial. In one embodiment, the CRC checksum may be calculated by dividing the data polynomial by the generator polynomial, where the remainder of the calculation becomes the CRC checksum. If the data is being shifted into CRC generation circuit 16 through dout 30, the polynomial division may be performed as the data is shifted through flip-flops 22.

At step 70, processor 12 determines if the CRC calculation is complete. If the calculation is not complete, the processor 12 continues to write the data in CRC generation circuit 12 at step 66 and continues to perform polynomial division at step 68. If the calculation is complete, the CRC checksum is appended at the end of the data at step 72. In one embodiment, the CRC checksum may be the final results stored in flip-flops 22 and may be read through CRC read bus 38.

The present disclosure has been described in terms of specific exemplary embodiments. In accordance with the present disclosure, the parameters for a system may be varied, typically with a design engineer specifying and selecting them for the desired application. For example, CRC generation circuit 16 may include fewer or more polynomial blocks 27 depending on the polynomial operations to be performed. Additionally, generator polynomials other than those listed in Table 1 may be programmed into CRC generation circuit 16 to provide the appropriate CRC equation. Further, it is contemplated that other embodiments, which may be devised readily by persons of ordinary skill in the art based on the teachings set forth herein, may be within the scope of the disclosure, which is defined by the appended claims. The present disclosure may be modified and practiced in different but equivalent manners that will be apparent to those skilled in the art and having the benefit of the teachings set forth herein.

What is claimed is:

1. A method for configuring a cyclic redundancy check (CRC) generation circuit to perform CRC on a data stream, comprising:
storing a generator polynomial associated with a CRC equation in a register, the generator polynomial including a length capable of varying such that the length has any value less than or equal to a number of bits associated with a CRC generation circuit;
selecting a bit position of the CRC generation circuit that corresponds to the length of the generator polynomial by using a first multiplexer to generate a feedback value; and
programming the CRC generation circuit to calculate a CRC checksum based on the generator polynomial stored in the register and the feedback value from the selected bit position.

2. The method of claim 1, further comprising determining the length of the generator polynomial based on a maximum term in the polynomial, the maximum term having an exponential value less than or equal to the number of bits associated with the CRC generation circuit.

3. The method of claim 1, wherein selecting the bit position in the CRC generation circuit comprises enabling an input of the first multiplexer corresponding to the selected bit position based on the length of the generator polynomial such that an output of the selected bit position is selected by the first multiplexer as the feedback value.

4. The method of claim 1, wherein the CRC generation circuit comprises a plurality of polynomial blocks connected in sequence such that each polynomial block represents a polynomial term of the generator polynomial, each polynomial block comprising:
a second multiplexer including a first mux input, a second mux input and a mux output, the first mux output operable to receive an output of a previous adjacent polynomial block;
a flip-flop including a flop input operable to receive the mux output of the second multiplexer and an flop output received by an input of a subsequent adjacent polynomial block; and
a feedback gate including a first gate input operable to receive the output of the previous adjacent polynomial block, a second gate input operable to receive the feedback value and a gate output received by the second mux input.

5. The method of claim 4, wherein the feedback gate comprises an exclusive OR (XOR) gate.

6. The method of claim 4, wherein programming the CRC generation circuit with the generator polynomial comprises generating the polynomial term by one of the polynomial blocks if the second multiplexer selects the output of the feedback gate.

7. The method of claim 1, wherein the register comprises a plurality of bits, each bit operable to determine whether a polynomial term is present in the generator polynomial.

8. The method of claim 1, further comprising:
storing a binary representation of the generator polynomial in a first register; and
storing a binary representation of the length of the generator polynomial in a second register.

9. Apparatus for configuring a cyclic redundancy check (CRC) generation circuit to perform CRC on a data stream, comprising:
a register operable to store a generator polynomial associated with a CRC equation, the generator polynomial including a length capable of varying such that the length has any value less than or equal to a maximum number of bits;
a first multiplexer coupled to the register and operable to generate a feedback value; and
a CRC generation circuit coupled to the register and the first multiplexer, the CRC generation circuit operable to calculate a CRC checksum based on the feedback value and the generator polynomial stored in the register, the feedback value selected from a bit position of the CRC generation circuit that corresponds to the length of the generator polynomial.

10. The apparatus of claim 9, wherein the length of the generator polynomial is determined based on a maximum term in the generator polynomial, the maximum term having an exponential value less than or equal to the number of bits associated with the CRC generation circuit.

11. The apparatus of claim 9, wherein the first multiplexer comprises:
a plurality of inputs corresponding to each bit position of the CRC generation circuit;
an output; and
a control input operable to enable the input corresponding to the selected bit position such that the feedback value is introduced at the output.

12. The apparatus of claim 9, wherein the CRC generation circuit comprises a plurality of polynomial blocks connected in sequence such that each polynomial block represents a polynomial term of the generator polynomial, each term block comprising:
a second multiplexer including a first mux input, a second mux input and a mux output, the first mux output operable to receive an output of a previous adjacent polynomial block;
a flip-flop including a flop input operable to receive the mux output of the second multiplexer and an flop output received by an input of a subsequent adjacent polynomial block; and
a feedback gate including a first gate input operable to receive the output of the previous adjacent polynomial block, a second gate input operable to receive the feedback value and a gate output received by the second mux input.

13. The apparatus of claim 12, wherein the feedback gate comprises an exclusive OR (XOR) gate.

14. The apparatus of claim 12, wherein the polynomial blocks generate the polynomial term if the second multiplexer selects the output of the feedback gate.

15. The apparatus of claim 9, wherein the register comprises a plurality of bits, each bit operable to determine whether a polynomial term is present in the CRC equation.

16. A microcontroller, comprising:
a processor operable to generate a data stream;
a register coupled to the processor and operable to store a generator polynomial associated with a CRC equation, the generator polynomial including a length capable of varying such that the length has any value less than or equal to a maximum number of bits;
a first multiplexer coupled to the register and operable to generate a feedback value; and
a CRC generation circuit coupled to the register and the first multiplexer, the CRC generation circuit operable to calculate a CRC checksum for the data stream based on the feedback value and the generator polynomial stored in the register, the feedback value selected from a bit position of the CRC generation circuit that corresponds to the length of the generator polynomial.

17. The microcontroller of claim 16, wherein the length of the generator polynomial is determined based on a maximum term in the generator polynomial, the maximum term having an exponential value less than or equal to the number of bits associated with the CRC generation circuit.

18. The microcontroller of claim 16, wherein the first multiplexer comprises:
a plurality of inputs corresponding to each bit position of the CRC generation circuit;
an output; and
a control input operable to enable the input corresponding to the selected bit position such that the feedback value is introduced at the output.

19. The microcontroller of claim 16, wherein the CRC generation circuit comprises a plurality of polynomial blocks connected in sequence such that each polynomial block represents a polynomial term of the generator polynomial, each term block comprising:
a second multiplexer including a first mux input, a second mux input and a mux output, the first mux output operable to receive an output of a previous adjacent polynomial block;
a flip-flop including a flop input operable to receive the mux output of the second multiplexer and an flop output received by an input of a subsequent adjacent polynomial block; and
a feedback gate including a first gate input operable to receive the output of the previous adjacent polynomial block, a second gate input operable to receive the feedback value and a gate output received by the second mux input.

20. The microcontroller of claim 19, wherein the feedback gate comprises an exclusive OR (XOR) gate.

21. The microcontroller of claim 19, wherein the polynomial blocks generate the polynomial term if the second multiplexer selects the output of the feedback gate.

22. The microcontroller of claim 16, wherein the microcontroller is fabricated as an integrated circuit.
